(19) United States
(12) Patent Application Publication
(10) Pub. No.: US 2023/0051800 A1
(43) Pub. Date: Feb. 16, 2023

(54) METHODS AND APPARATUS FOR PLASMA SPRAYING SILICON CARBIDE COATINGS FOR SEMICONDUCTOR CHAMBER APPLICATIONS

(71) Applicant: APPLIED MATERIALS, INC., Santa Clara, CA (US)

(72) Inventors: YIKAI CHEN, San Jose, CA (US); ANIRUDDHA PAL, SANTA CLARA, CA (US); SAURABH M. CHAUDHARI, San Jose, CA (US); YAO-HUNG YANG, Santa Clara, CA (US); SIAMAK SALIMIAN, Santa Clara, CA (US); TOM K. CHO, LOS ALTOS, CA (US)

(21) Appl. No.: 17/759,257

(22) PCT Filed: Jan. 27, 2021
(86) PCT No.: PCT/US2021/015225

§ 371 Date: Jul. 21, 2022

Related U.S. Application Data
(60) Provisional application No. 62/966,536, filed on Jan. 27, 2020.

(51) Int. Cl. C23C 4/10; C23C 4/134; C04B 35/565; C04B 35/622

(52) U.S. Cl. CPC C23C 4/10; C23C 4/134; C04B 35/565; C04B 35/62218; C04B 2235/3826

(57) ABSTRACT

Methods and apparatus for producing bulk silicon carbide and producing silicon carbide coatings are provided herein. The method includes feeding a mixture of silicon carbide and ceramic into a plasma sprayer. The plasma generates a stream towards a substrate forming a bulk material or optionally a coating on the substrate such as an article upon contact therewith. In embodiments, the substrate can be removed, leaving a component part fabricated from bulk silicon carbide.

### FIELD

Embodiments of the present disclosure generally relate to silicon carbide (SiC) coatings atop semiconductor manufacturing components or to the formation of silicon carbide bulk material.

### BACKGROUND

In the semiconductor industry, devices are fabricated by a number of manufacturing processes producing structures of ever-decreasing size. Some manufacturing processes such as plasma etch and plasma clean processes expose a substrate support (e.g., an edge of the substrate support during wafer processing and the full substrate support during chamber cleaning) to a high-speed stream of plasma to etch or clean the substrate. The plasma may be highly corrosive and may corrode processing chambers and other surfaces exposed to the plasma.

Plasma spray coatings are utilized to protect chamber components from processing conditions, in order to enhance on-wafer defect performance as well as the lifetime of the component. The inventors have found that silicon carbide in accordance with the present disclosure may be useful as a coating; however application as a coating is problematic as silicon carbide is typically formed by lengthy deposition processes such as chemical vapor deposition (CVD) with a high thermal budget also leading to problems with bulk silicon carbide production. The inventors have found making silicon carbide in bulk is problematic for having a relatively high cost and high thermal budget due to the temperature and a lengthy production time.

Thus, what is needed are plasma spraying of silicon carbide coatings, or silicon carbide bulk material.

### SUMMARY

Methods and apparatus for forming silicon carbide coatings atop semiconductor manufacturing articles or to the formation of silicon carbide bulk material are provided herein. In some embodiments, a method of plasma spray coating silicon carbide, includes: feeding a silicon carbide powder into a plasma sprayer; generating a stream directed towards a substrate; and contacting the substrate with the stream under conditions sufficient to form a coating atop the substrate.

In some embodiments, the present disclosure relates to a method, comprising: selecting a plasma power of between about 10-200 kW for a plasma spraying system; flowing gas through the plasma spraying system at a selected gas flow rate of about 30-200 L/min; feeding powder comprising a silicon carbide with one or more ceramic dopants into the plasma spraying system at a selected powder feed rate of about 5-100 g/min; and forming a coating on a substrate based on the selected power, the selected gas flow rate and the selected powder feed rate.

In some embodiments, the present disclosure relates to a method of forming silicon carbide, including: feeding a silicon carbide powder into a plasma sprayer; generating a stream directed towards a substrate; contacting the substrate with the stream under conditions sufficient to form a bulk material atop the substrate; and removing the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a sectional view of a processing chamber according to an embodiment of the present disclosure.

FIG. 2 depicts a sectional view of a plasma spray device according to an embodiment of the present disclosure.

FIGS. 3A and 3B depict a sectional view of an exemplary chamber component with one and two coatings, respectively, according to an embodiment of the present disclosure.

FIG. 4 is a flow diagram illustrating a process for producing a coating in accordance with an embodiment of the present disclosure.

FIG. 5 is a flow diagram illustrating a process for producing a coating in accordance with an embodiment of the present disclosure.

FIG. 6 is a flow diagram illustrating a process for producing silicon carbide in accordance with an embodiment of the present disclosure.

To facilitate understanding, identical reference numerals have been used, where possible, to designate identical elements common to the figures. The figures are not drawn to scale and may be simplified for clarity. Elements and features of one embodiment may be beneficially incorporated in other embodiments without further recitation.

### DETAILED DESCRIPTION

Embodiments of the present disclosure provide methods and apparatus for forming silicon carbide coatings atop semiconductor manufacturing articles or to the formation of silicon carbide bulk material. In some embodiments, a method of plasma spray coating silicon carbide, includes: feeding a silicon carbide powder into a plasma sprayer; generating a stream directed towards a substrate; and contacting the substrate with the stream under conditions sufficient to form a coating atop the substrate. In embodiments, the silicon carbide powder includes a ceramic dopant such as one or more of yttrium aluminum garnet (Y₃Al₅O₁₂) or (YAG), Y₄Al₂O₉ (YAM), erbium oxide (Er₂O₃), gadolinium(III) oxide (Gd₂O₃), Gd₃Al₅O₁₂ (GAG), yttrium(III) fluoride (YF₃), Al2O3, Y₂O₃, YOF, neodymium(III) oxide (Nd₂O₃), Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, a ceramic characterized as high-performance material (HPM ceramic), or combinations thereof. In embodiments, the coatings of the present disclosure may alternatively have other compositions as described further below. The improved erosion resistance to multiple different plasma environments provided by one or more of the disclosed coatings may improve the service life of the chamber component, while reducing maintenance and manufacturing cost. In embodiments, the coatings of the present disclosure reduce or eliminate porosity, cracks, and rough surface finishes, which detract from the performance of the substrate or semiconductor component, or protect against the formation of porosity, cracks, and rough surface finishes when subjected to harsh environments, e.g., during a plasma spraying process. Further, in embodiments, benefits of the present disclosure include the formation of silicon carbide in bulk, relatively quickly with a relatively short deposition processes having a low or reduced thermal budget. Further, such bulk silicon carbide can be used to form the above noted components, rather than just a coating disposed atop the component.

In some embodiments, the coatings of the present disclosure are characterized as plasma resistance coating materials such as material resistant to erosion and corrosion due to exposure to plasma processing conditions. Plasma processing conditions may include, for example, plasma generated from halogen-containing gases, such as C₂F₆, SF₆, SiCl₄, HBR, NF₃, CF₄, CHF₃, CH₂F₃, F, NF₃, Cl₂, CCl₄, BCl₃ and SiF₄, among others, and other gases such as O₂, or N₂O. In some embodiments, the resistance of the coating material to plasma may be measured through “etch rate” (ER), which may have units of Angstrom/min (A/min), throughout the duration of the coated components' operation and exposure to plasma. In some embodiments, the plasma resistance may also be measured through an erosion rate having the units of nanometer/radio frequency hour (nm/RFHr), where one RFHr represents one hour of processing in plasma processing conditions. Measurements may be taken after different processing times. For example, measurements may be taken before processing, after 50 processing hours, after 150 processing hours, after 200 processing hours, and so on. A single plasma resistant material may have multiple different plasma resistance or erosion rate values. For example, a plasma resistant material may have a first plasma resistance or erosion rate associated with a first type of plasma and a second plasma resistance or erosion rate associated with a second type of plasma.

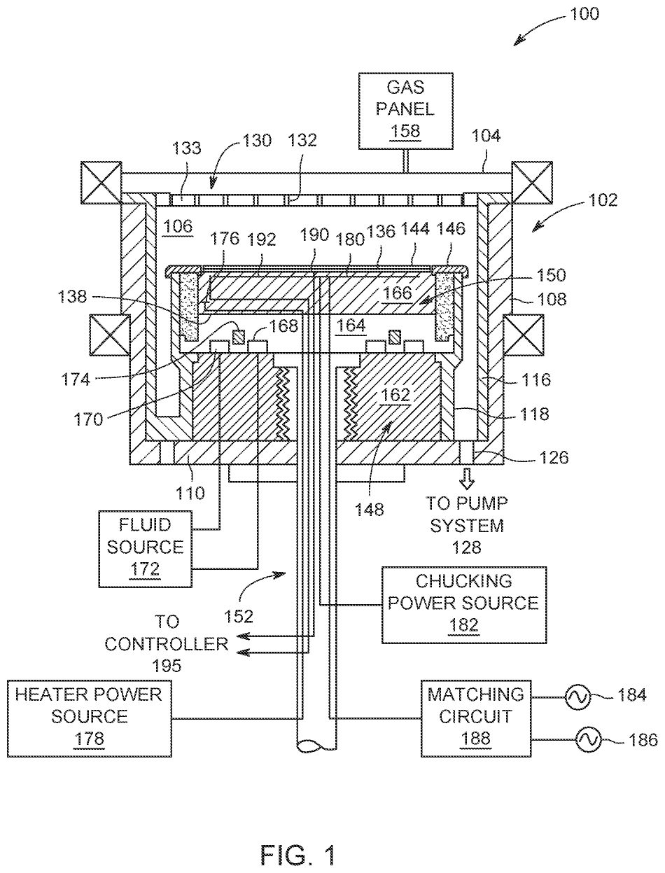

Referring now to FIG. 1, a is a sectional view of a semiconductor processing chamber 100 having one or more chamber components (or component parts) suitable for coating with a coating layer or being formed from bulk silicon carbide in accordance with embodiments of the present disclosure is shown. The processing chamber 100 may be suitable for processes in which a corrosive plasma environment is provided. For example, the processing chamber 100 may be a chamber for a plasma etcher or plasma etch reactor, a plasma cleaner, and so forth. Examples of chamber components or articles including a coating layer or being formed at least in part by bulk silicon carbide include a substrate support assembly 148, an electrostatic chuck (ESC) 150, a ring (e.g., a process kit ring or single ring), a chamber wall, a base, a gas distribution plate, a showerhead, a liner, a liner kit, a shield, a plasma screen, a flow equalizer, a cooling base, a chamber viewport, a chamber lid, and so on. In embodiments, the coating layer or the bulk silicon carbide, which are described in greater detail below, may include, silicon carbide powder alone or as a mixture of silicon carbide and one or more dopants such as one or more ceramic materials or one or more metals. In some embodiments, the one or more ceramic materials include Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, a ceramic material characterized as high-performance material (HPM ceramic), or combinations thereof. In some embodiments, the one or more metals include, but are not limited to, Si, Al, Y, Er, Mg, Gd, Ti, Zr, Nd, Ce, La, Hf, or Ca

Referring to FIG. 1, the substrate support assembly 148 has a coating layer 136 in accordance with the coatings of the present disclosure. However, any of the other chamber components may also include a coating layer in accordance with the present disclosure.

In embodiments, the processing chamber 100 includes a chamber body 102 and a showerhead 130 enclosing an interior volume 106. Alternatively, the showerhead 130 may be replaced by a lid and a nozzle in some embodiments. The chamber body 102 may be fabricated from aluminum, stainless steel or other suitable material. The chamber body 102 generally includes sidewalls 108 and a bottom 110. One or more of showerhead 130 (or lid and/or nozzle), sidewalls 108 and/or bottom 110 may include a coating layer of the present disclosure. In embodiments, an outer liner 116 may be disposed adjacent the sidewalls 108 to protect the chamber body 102. The outer liner 116 may be fabricated and/or coated with a coating layer of the present disclosure. In embodiments, the outer liner 116 is fabricated from aluminum oxide.

In some embodiments, an exhaust port 126 may be defined in the chamber body 102 and may couple the interior volume 106 to a pump system 128. The pump system 128 may include one or more pumps and throttle valves utilized to evacuate and regulate the pressure of the interior volume 106 of the processing chamber 100. In embodiments, the 132 130 may be supported on the sidewall 108 of the chamber body 102. The showerhead 130 (or lid) may be opened to allow access to the interior volume 106 of the processing chamber 100 and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 includes a gas distribution plate (GDP) 133 having multiple gas delivery holes 132 throughout the GDP 133. The showerhead 130 may include the GDP 133 bonded to an aluminum base or an anodized aluminum base. The GDP 133 may be made from Si or SiC, or may be a ceramic such as Y₂O₃, Al₂O₃, YAG, and so forth. In embodiments, the GDP may be coated with a coating in accordance with the present disclosure.

For processing chambers used for conductor etch (etching of conductive materials), a lid may be used rather than a showerhead. The lid may include a center nozzle sized to fits into a center hole of the lid. In embodiments, the lid, showerhead base 104, GDP 133 and/or nozzle may be coated with a coating of the present disclosure.

Examples of processing gases for processing substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. In embodiments, the coating layer of the present disclosure may be resistant to erosion from some or all of the gases above and/or plasma generated from the gases above. Examples of carrier gases include N₂, He, Ar, and other gases inert to process gases (e.g., non-reactive gases). In some embodiments, the substrate support assembly 148 is disposed in the interior volume 106 of the processing chamber 100 below the showerhead 130 or lid. The substrate support assembly 148 holds the substrate 144 during processing. A ring 146 (e.g., a single ring) may cover a portion of the electrostatic chuck 150 and may protect the covered portion from exposure to plasma during processing. The ring 146 may be silicon or quartz and in embodiments, may be coated in accordance with the present disclosure. In some embodiments, an inner liner 118 may be coated in accordance with the present disclosure on the periphery of the substrate support assembly 148. In some embodiments, the inner liner 118 may be a halogen-containing gas resistant material. In embodiments, the inner liner 118 may be fabricated from the same materials of the outer liner 116. Additionally, the inner liner 118 may be coated with a coating of the present disclosure.

In embodiments, the substrate support assembly 148 includes a mounting plate 162 supporting a pedestal 152, and an electrostatic chuck 150. The electrostatic chuck 150 further includes a thermally conductive base 164 and an electrostatic puck 166 bonded to the thermally conductive base by a bond 138, which may be a silicone bond in some embodiments. In embodiments, an upper surface of the electrostatic puck 166 is covered by the coating layer 136 in accordance with the present disclosure. In embodiments, the coating layer 136 is disposed on the upper surface of the electrostatic puck 166. In another embodiment, the coating layer 136 is disposed on the entire exposed surface of the electrostatic chuck 150 including the outer and side periphery of the thermally conductive base 164 and the electrostatic puck 166. The mounting plate 162 is coupled to the bottom 110 of the chamber body 102 and includes passages for routing utilities (e.g., fluids, power lines, sensor leads, etc.) to the thermally conductive base 164 and the electrostatic puck 166.

In embodiments, the thermally conductive base 164 and/or electrostatic puck 166 may include one or more optional embedded heating elements such as heater 176, embedded thermal isolators 174 and/or conduits 168, 170 to control a lateral temperature profile of the substrate support assembly 148. The conduits 168, 170 may be fluidly coupled to a fluid source 172 to circulate a temperature regulating fluid through the conduits 168, 170. In embodiments, the embedded thermal isolator 174 may be disposed between the conduits 168, 170. In embodiments, the heater 176 is regulated by a heater power source 178. The conduits 168, 170 and heater 176 may be utilized to control the temperature of the thermally conductive base 164, thus heating and/or cooling the electrostatic puck 166 and a substrate 144 (e.g., a wafer) being processed. The temperature of the electrostatic puck 166 and the thermally conductive base 164 may be monitored using a plurality of temperature sensors 190, 192, which may be monitored using a controller 195.

In some embodiments, the electrostatic puck 166 may further include multiple gas passages such as grooves, mesas and other surface features, which may be formed in an upper surface of the electrostatic puck 166 and/or the coating layer 136. The gas passages may be fluidly coupled to a source of a heat transfer (or backside) gas such as helium via holes drilled in the electrostatic puck 166. In operation, the backside gas may be provided at controlled pressure into the gas passages to enhance the heat transfer between the electrostatic puck 166 and the substrate 144. The electrostatic puck 166 includes at least one clamping electrode 180 controlled by a chucking power source 182. The clamping electrode 180 (or other electrode disposed in the electrostatic puck 166 or conductive base 164) may further be coupled to one or more RF power sources 184, 186 through a matching circuit 188 for maintaining a plasma formed from process and/or other gases within the processing chamber 100. The RF power sources 184, 186 are generally capable of producing an RF signal having a frequency from about 50 kHz to about 3 GHz, with a power output of up to about 10,000 Watts.

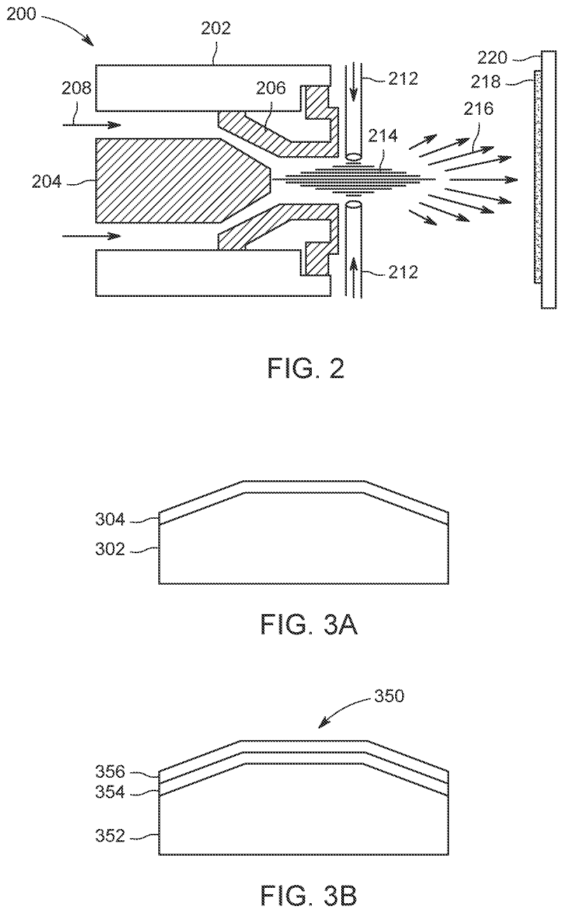

Referring now to FIG. 2, a sectional view of a plasma spray device 200 according to embodiments of the present disclosure is shown. In embodiments, the plasma spray device 200 is a type of thermal spray system for performing deposition of silicon carbide alone or in combination with one or more dopants such as ceramic materials. In some embodiments, the plasma spray device 200 is configured for utilizing a particle-based distribution of silicon carbide powder alone or in combination with one or more ceramic materials to deposit a coating layer of the present disclosure on an article or substrate. In embodiments, spraying may be performed by spraying the feedstock using atmospheric plasma spray, high velocity oxy-fuel (HVOF), warm spraying, vacuum plasma spraying (VPS), and low pressure plasma spraying (LPPS). In some embodiments, the plasma spray device 200 may include a casing 202 for encasing a nozzle anode 206 and a cathode 204. The casing 202 permits gas flow 208 through the plasma spray device 200 and between the nozzle anode 206 and the cathode 204. An external power source may be used to apply a voltage potential between the nozzle anode 206 and the cathode 204. The voltage potential produces an arc between the nozzle anode 206 and the cathode 204 for igniting the gas flow 208 to produce a plasma gas. The ignited plasma gas flow produces a high-velocity plasma plume 214 directed out of the nozzle anode 206 and toward an article or substrate 220. A distance between a distal end of the nozzle anode 206 and the substrate 220 (i.e., a gun distance) may be between about 50 mm and about 500 mm, in certain embodiments.

In embodiments, the plasma spray device 200 may be located in a chamber or atmospheric booth. In some embodiments, the gas flow 208 may be a gas or gas mixture including, but not limited to argon, nitrogen, hydrogen, helium, and combinations thereof. A flow rate of the gas flow 208 may be, for example, between about 30 L/min and about 200 L/min, A voltage potential applied between the nozzle anode 206 and the cathode 204 may be an AC waveform, a DC waveform, or a combination thereof, and may be between about 20 V and about 500 V. The applied potential is generally capable of providing a gun power of 10 kW or greater with a gun current of up to 1000 A or greater.

In some embodiments, the plasma spray device 200 may be equipped with one or more powder lines 212 to deliver a feedstock (e.g., a silicon carbide powder mixture, etc.) into the plasma plume 214, for example, at a flow rate between 5 g/min and about 100 g/min. In some embodiments, several powder lines 212 may be arranged on one side or symmetrically around the plasma plume 214. In some embodiments, the powder lines 212 may be arranged in a perpendicular fashion to the plasma plume 214 direction, as depicted in FIG. 2. In other embodiments, the powder lines 212 may be adjusted to deliver the feedstock into the plasma plume at a different angle (e.g., 45 degrees), or may be located at least partially inside of the casing 202 to internally inject the powder into the plasma plume 214. In some embodiments, each powder line 212 may provide a different feedstock, which may be utilized to vary a composition of a resulting coating across the article or substrate 220.

In embodiments, the feedstock is a silicon carbide powder, a feeder system may be utilized to deliver the silicon carbide powder to the powder lines 212. In some embodiments, the feeder system includes a flow controller to maintain a constant flow rate during coating. The powder lines 212 may be cleaned before and after the coating process using.

In some embodiments, the feedstock contains a silicon carbide powder. In some embodiments, the silicon and carbide are present in a ratio of 1:1. In some embodiments, the silicon carbide powder may include one or more metals (including metal salts) including, but not limited to, pure metals, metal nitrate, metal acetate, metal sulfate, metal chloride, metal alkoxide, or combinations thereof. In some embodiments, the silicon carbide powder is a mixture of silicon carbide and one or more dopants. In some embodiments, the one or more dopants comprise one or more metals or ceramic materials. In some embodiments, the one or more metals include, but are not limited to, Si, Al, Y, Er, Mg, Gd, Ti, Zr, Nd, Ce, La, Hf, or Ca; and the one or more ceramic materials comprise one or more of Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, or a ceramic material characterized as high-performance material (HPM ceramic).

In some embodiments, the plasma plume 214 can reach temperatures between about 2000° C. to about 10000° C. The intense temperature experienced by a feedstock such as silicon carbide (powder) alone or in combination with a one or more metals or ceramic materials when injected into the plasma plume 214 may become molten, generating a stream 216 propelled toward the article or substrate 220. Upon impact with the article or substrate 220, the molten particles rapidly solidify on the article or substrate, forming a coating 218 of the present disclosure.

In some embodiments, parameters can affect the thickness, density, and roughness of the coating 218 include the feedstock conditions, the concentrations of amounts and relative quantities of different silicon carbide powder admixtures with one or more dopants in accordance with the present disclosure, the feed rate 5-100 g/min, the plasma gas composition Ar, Ar/He or Ar/H2, the gas flow rate 30-200 L/min, the energy input 200 A to 1000 A, the spray distance 50-300 mm, and article or substrate temperature during deposition.

Referring now to FIGS. 3A and 3B, a sectional view is shown of an exemplary chamber component with one and two coatings, respectively, according to embodiments of the present disclosure. Referring to FIG. 3A, at least a portion of a base or body 302 of an article or substrate is coated by a coating 304 of the present disclosure. The article or substrate may be the same as the article or substrate 220 described with respect to FIG. 2) may be a chamber component, such as a substrate support assembly, an electrostatic chuck (ESC), a ring (e.g., a process kit ring or single ring), a chamber liner, a showerhead base, a gas distribution plate, a liner, a liner kit, a shield, a plasma screen, a flow equalizer, a cooling base, a chamber viewport, a chamber lid, and so on. The body 302 of the article or substrate may be a metal, a ceramic, a metal-ceramic composite, a polymer, or a polymer-ceramic composite.

In some embodiments, various chamber components are composed of different materials. For example, an electrostatic chuck may be composed of a ceramic such as Al₂O₃ (alumina), AlN (aluminum nitride), TiO (titanium oxide), TiN (titanium nitride) or SiC (silicon carbide) bonded to an anodized aluminum base.

Referring to FIG. 3A, a body 302 of the article or substrate may include one or more surface features. For an electrostatic chuck, surface features may include mesas, sealing bands, gas channels, helium holes, and so forth. For a showerhead, surface features may include a bond line, hundreds or thousands of holes for gas distribution, divots or bumps around gas distribution holes, and so forth. Other chamber components may have other surface features.

In some embodiments, the coating 304 of the present disclosure is formed on the body 302 and may conform to the surface features of the body 302. As shown, the coating 304 maintains a relative shape of the upper surface of the body 302 (e.g., telegraphing the shapes of the mesa). Additionally, the coating may be thin enough so as not to plug holes in the showerhead or helium holes in the electrostatic chuck. In one embodiment, the coating 304 has a thickness of below about 20 micrometers, or below about 10 micrometers. In a further embodiment, the coating 304 has a thickness of between about 10 micrometers to about 500 micrometers. The coating 304 may be deposited on the body 302 using the plasma spray device 200 described with respect to FIG. 2.

Referring to FIG. 3B, at least a portion of a base or body 352 of an article or substrate 350 is coated with two coatings: a first coating 354 and a second coating 356 deposited on the first coating 354. In some embodiments, the first coating 354 may be a coating performed using a standard deposition technique, such as dry plasma spraying of a powder, thermal deposition, sputtering, etc. The first coating 354 may be a ceramic coating having high surface roughness as well as surface defects such as cracks and pores. Accordingly, the second coating 356 may be deposited onto the first coating 354. The second coating may be a coating of the present disclosure using, for example, the plasma spray device 200 described with respect to FIG. 2. In some embodiments, the first and second coating may both be coatings of the present disclosure with different compositions.

In some embodiments, the first and second coatings 354, 356 are merely illustrative, and any suitable number of coatings may be deposited on the body 352, forming a coating stack. One or more of the coatings in the coating stack may be a coating in accordance with the present disclosure. The coatings in the coating stack may all have the same thickness, or they may have varying thicknesses. Each of the coatings in the coating stack may have a thickness of less than about 100 micrometers, and about 50 micrometers in some embodiments. In one example, for the two-layer stacking, as depicted in FIG. 3B, the first coating 354 may have a thickness of about 100 micrometers, and the second coating 356 may have a thickness of about 100 micrometers. In another example, first coating 356 may be a layer comprised of a first composition having a thickness of about 10 micrometers, and the second coating 356 may be coating of the present disclosure having a thickness of about 500 micrometers.

In another example, each of the body and one or more coatings may have a different coefficient of thermal expansion. The greater the mismatch in the coefficient of thermal expansion between two adjacent materials, the greater the likelihood one of the materials will eventually crack, peel away, or otherwise lose a bond to the other material. The first and second coatings 354, 356 may be formed in such a way to minimize mismatch of the coefficient of thermal expansion between adjacent coatings (or between the first coating 354 and the body 352). For example, the body 352 may have a first coefficient of thermal expansion, and the first coating may have a coefficient of thermal expansion closest to the first coefficient of thermal expansion, followed by a third coefficient of thermal expansion for the second coating.

By performing deposition using silicon carbide powder alone or in combination with one or more ceramics or one or more metals as described herein, examples of coating compositions may include silicon carbide in an amount of 20 to 90 percent weight of the total coating composition and one or more ceramics or one or more metals in an amount of 10% to 80 percent weight of the total coating composition. In some embodiments, coating compositions or layers formed may include silicon carbide in an amount of about 60 percent weight of the total coating composition and one or more ceramics or one or more metals in an amount of about 40 percent weight of the total coating composition. In some embodiments, coating compositions or layers formed may include silicon carbide in an amount of about 70 percent weight of the total coating composition and one or more ceramics or one or more metals in an amount of about 30 percent weight of the total coating composition. In some embodiments, coating compositions or layers formed may include silicon carbide in an amount of about 80 percent weight of the total coating composition and one or more ceramics or one or more metals in an amount of about 20 percent weight of the total coating composition.

In some embodiments, the coatings may also be based on a powder form of silicon carbide mixed any of the ceramics or metals. For example, silicon carbide precursor may be a powder present in the amount of 60 to 80 percent weight of the total precursor composition and one or more ceramics or one or more metals in an amount of 20% to 40 percent weight of the total precursor composition. In embodiments, the one or more ceramics include one or more of Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, or a ceramic material characterized as high-performance material (HPM ceramic). In embodiments, the one or more metals include one or more of Si, Al, Y, Er, Mg, Gd, Ti, Zr, Nd, Ce, La, Hf, or Ca.

In some embodiments, silicon carbide precursor may be a powder present in the amount of 60 to 70 percent weight of the total precursor composition and one or more ceramics or one or more metals in an amount of 30% to 40 percent weight of the total precursor composition. In embodiments, the one or more ceramics include one or more of Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, or a ceramic material characterized as high-performance material (HPM ceramic). In embodiments the one or more ceramics include a combination of YAG, YAM, and/or EAG. In embodiments, the one or more metals include one or more of Si, Al, Y, Er, Mg, Gd, Ti, Zr, Nd, Ce, La, Hf, or Ca.

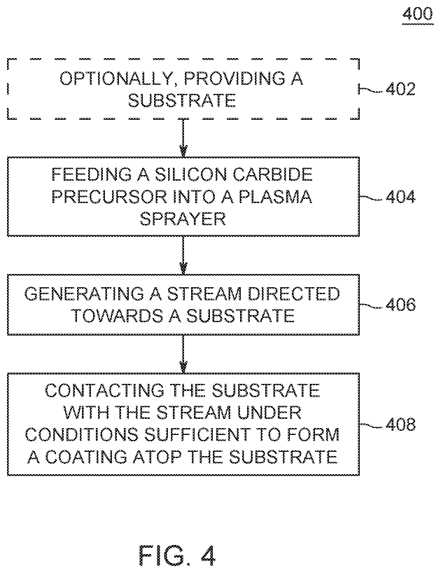

FIG. 4 is a flow diagram illustrating a process 400 of plasma spray coating silicon carbide in accordance with the present disclosure. At process sequence 402, optionally, a substrate is provided for coating. The substrate may be any substrate or article described above suitable for coating in accordance with the present disclosure. In some embodiments, the substrate is a wafer (e.g., a silicon wafer substrate). In some embodiments, the substrate is an article suitable as a chamber component as described with respect to FIG. 1. For example, the substrate or article could be any of, but not limited to, a lid, a nozzle, an electrostatic chuck (e.g., ESC 150), a showerhead (e.g., showerhead 130), a liner (e.g., outer liner 116 or inner liner 118) or liner kit, or a ring (e.g., ring 146).

At process sequence 404, a silicon carbide powder is fed into a plasma sprayer. In embodiments, the silicon carbide powder is pure SiC, or a mixture of SiC and one or more dopants such as ceramics or metals described above. In embodiments, the silicon carbide powder is a mixture of silicon carbide and one or more dopants. In embodiments, the one or more dopants comprise one or more ceramic materials or one or more metals. In embodiments, the one or more ceramic materials comprise one or more of Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, or a ceramic material characterized as high-performance material (HPM ceramic). In embodiments, the one or more metals include one or more of Si, Al, Y, Er, Mg, Gd, Ti, Zr, Nd, Ce, La, Hf, or Ca. In embodiments, the silicon carbide powder may be fed into the plasma sprayer (e.g., the plasma spray device 200) using a powder line (e.g., one or more of the powder lines 212).

At process sequence 406, the plasma sprayer generates a stream directed toward the substrate or article. As the silicon carbide powder enters a plasma plume generated by the plasma sprayer (e.g., plasma plume 214), the silicon carbide powder alone or in combination with one or more ceramics or one or more metals as described above are melted into a stream of silicon carbide powder that is propelled toward the substrate (e.g., substrate 220).

At process sequence 408, contacting the substrate with the stream under conditions sufficient to form a coating atop the substrate is performed. A composition of the resultant coating may be silicon carbide (SiC) alone, or a mixture such as silicon carbide in an amount of 60 to 80 percent weight of the total composition, and ceramic or metal in an amount of 20 to 40 percent weight of the total composition. In embodiments, the coating comprises a mixture of silicon carbide and one or more dopants. In embodiments, the one or more dopants comprise one or more ceramic materials or one or more metals. In embodiments, the one or more ceramic materials comprise one or more of Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, or a ceramic material characterized as high-performance material (HPM ceramic). In embodiments, the one or more metals include one or more of Si, Al, Y, Er, Mg, Gd, Ti, Zr, Nd, Ce, La, Hf, or Ca.

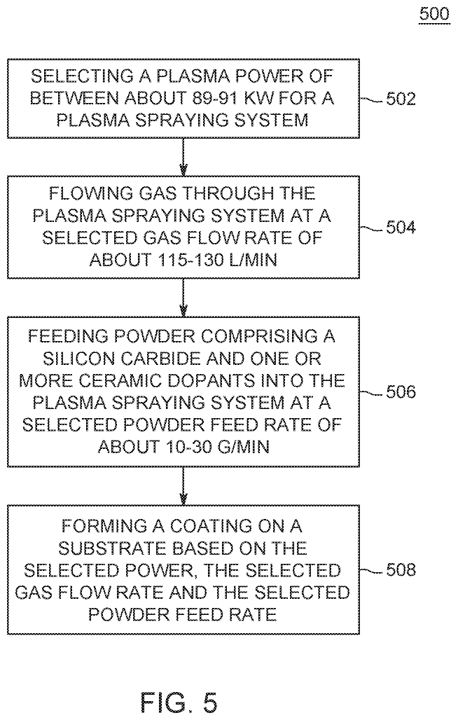

Referring now to FIG. 5, a method 500 includes at process sequence 502 selecting a plasma power of between about 10-200 kW for a plasma spraying system. Next at process sequence 504 the method includes flowing gas through the plasma spraying system at a selected gas flow rate of about 30-200 L/min. At process sequence 506 the method includes feeding powder comprising a silicon carbide and one or more ceramic or metal dopants into the plasma spraying system at a selected powder feed rate of about 5-100 g/min. At process sequence 508 the method includes forming a coating on a substrate based on the selected power, the selected gas flow rate and the selected powder feed rate. In some embodiments, the method includes setting a distance between a nozzle of the plasma spraying system and the substrate to about 50-500 mm.

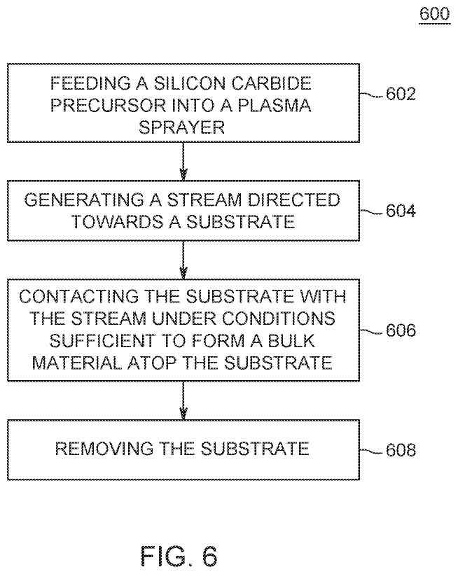

In some embodiments, the present disclosure relates to forming bulk silicon carbide. Referring now to FIG. 6, method 600 includes a method of forming silicon carbide. At process sequence 602 the method includes feeding a silicon carbide powder into a plasma sprayer. At process sequence 604 the method includes generating a stream directed towards a substrate. At process sequence 606 the method includes contacting the substrate with the stream under conditions sufficient to form a bulk material atop the substrate. At process sequence 608 the method includes removing the substrate, for example, to obtain a bulk silicon carbide part. In embodiments, the silicon carbide powder is a mixture of silicon carbide and one or more dopants. In embodiments, the one or more dopants comprise one or more ceramic materials or one or more metals. In embodiments, the one or more ceramic materials comprise one or more of Y₃Al₅O₁₂ (YAG), Y₄Al₂O₉ (YAM), Er₂O₃, Gd₂O₃, Gd₃Al₅O₁₂ (GAG), YF₃, Al2O3, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, or a ceramic material characterized as high-performance material (HPM ceramic). In embodiments, the one or more metals include one or more of Si, Al, Y, Er, Mg, Gd, Ti, Zr, Nd, Ce, La, Hf, or Ca.

In embodiments, the bulk material comprises a mixture of silicon carbide and one or more dopants. In embodiments, the one or more dopants comprise one or more ceramic materials or one or more metals. In some embodiments, the one or more ceramic materials are selected from the group consisting of: Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, a ceramic material characterized as high-performance material (HPM ceramic), and combinations thereof. In embodiments, the one or more metals include one or more of Si, Al, Y, Er, Mg, Gd, Ti, Zr, Nd, Ce, La, Hf, or Ca. In some embodiments, the bulk material is formed to a predetermined thickness such as greater than 5 mm. In some embodiments, the bulk material comprises silicon carbide in an amount of 20 to 90 percent weight of the total bulk material composition and one or more ceramics or one or more metals in an amount of 10 to 80 percent weight of the total coating composition.

In some embodiments, the present disclosure relates to a method of plasma spray coating silicon carbide, including: feeding a silicon carbide powder into a plasma sprayer; generating a stream directed towards a substrate; and contacting the substrate with the stream under conditions sufficient to form a coating atop the substrate. In some embodiments, the silicon carbide powder is a mixture of silicon carbide and one or more dopants. In some embodiments, the one or more dopants comprise one or more ceramic materials or one or more metals, such as any of the one or more ceramics or one or more metals as described above. In some embodiments, the coating comprises a mixture of silicon carbide and one or more dopants. In some embodiments, the one or more dopants comprise one or more ceramic materials or one or more metals, such as any of the one or more ceramics or one or more metals as described above. In some embodiments, the coating comprises silicon carbide in an amount of 20 to 90 percent weight of the total coating composition and one or more ceramics or one or more metals in an amount of 10 to 80 percent weight of the total coating composition.

In some embodiments, the present disclosure relates to a method, including: selecting a plasma power of between about 10-200 kW for a plasma spraying system; flowing gas through the plasma spraying system at a selected gas flow rate of about 30-200 L/min; feeding powder comprising a silicon carbide and one or more ceramic dopants into the plasma spraying system at a selected powder feed rate of about 5-100 g/min; and forming a coating on a substrate based on the selected power, the selected gas flow rate and the selected powder feed rate. In some embodiments, the method includes setting a distance between a nozzle of the plasma spraying system and the substrate to about 50-500 mm. In some embodiments, the method includes setting a gun current to about 100-1000 A.

In some embodiments, the present disclosure relates to a method of forming silicon carbide, comprising: feeding a silicon carbide powder into a plasma sprayer; generating a stream directed towards a substrate; contacting the substrate with the stream under conditions sufficient to form a bulk material atop the substrate; and removing the substrate, for example, to obtain a component part fabricated from the bulk silicon carbide (e.g., any of the process chamber components disclosed above). In some embodiments, the present disclosure the silicon carbide powder is a mixture of silicon carbide and one or more dopants. In some embodiments, the one or more dopants comprise one or more ceramic materials or one or more metals. The one or more ceramics and the one or more metals can be any of the one or more ceramics or one or more metals as described above. In some embodiments, the mixture comprises silicon carbide in an amount of 20 to 90 percent weight of the total mixture and one or more ceramics or one or more metals in an amount of 10 to 80 percent weight of the total mixture.

While the foregoing is directed to embodiments of the present disclosure, other and further embodiments of the disclosure may be devised without departing from the basic scope thereof.

1. A method of forming a bulk silicon carbide part, comprising:
feeding a silicon carbide powder into a plasma sprayer;
generating a stream directed towards a substrate;
contacting the substrate with the stream under conditions sufficient to form a bulk material atop the substrate; and
removing the substrate to obtain the bulk silicon carbide part.

2. The method of claim 1, wherein the silicon carbide powder is a mixture of silicon carbide and one or more dopants.

3. The method of claim 2, wherein the one or more dopants comprise one or more ceramic materials.

4. The method of claim 3, wherein the one or more ceramic materials comprise one or more of Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅12, Nd₄Al₂O₉, NdAlO₃, a ceramic compound composed of Y₄Al₂O₉ and a solid-solution of Y₂O₃—ZrO₂, or a ceramic material characterized as high-performance material (HPM ceramic).

5. The method of claim 3, wherein the one or more dopants comprise one or more metals.

6. The method of claim 5, wherein the one or more metals comprise one or more of Si, Al, Y, Er, Mg, Gd, Ti, Zr, Nd, Ce, La, Hf, or Ca.

7. The method of claim 2, wherein the mixture comprises silicon carbide in an amount of 20 to 90 percent weight of the total mixture and one or more ceramics or metals in an amount of 10 to 80 percent weight of the total mixture.

8. The method of claim 1, wherein the bulk material comprises a mixture of silicon carbide and one or more dopants.

9. The method of claim 8, wherein the one or more dopants comprise one or more ceramic materials.

10. The method of claim 9, wherein the one or more ceramic materials are selected from the group consisting of: Y₃Al₅O₁₂ (YAG), Y₄Al₂O₉ (YAM), Er₂O₃, Gd₂O₃, Gd₃Al₅O₁₂ (GAG), YF₃, Al2O3, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, a ceramic material characterized as high-performance material (HPM ceramic), and combinations thereof.

11. The method of claim 8, wherein the one or more dopants comprise one or more metals.

12. The method of claim 11, wherein the one or more metals comprise one or more of Si, Al, Y, Er, Mg, Gd, Ti, Zr, Nd, Ce, La, Hf, or Ca.

13. The method of claim 1, where the bulk material is formed to a thickness greater than 5 mm.

14. The method of claim 1, wherein the bulk material comprises silicon carbide in an amount of 20 to 90 percent weight of the total bulk material composition and one or more ceramics or metals in an amount of 10 to 80 percent weight of the total bulk material composition.

15. A silicon carbide bulk part produced by the method of claim 1.

16. The silicon carbide bulk part of claim 15, wherein the bulk material comprises silicon carbide in an amount of 20 to 90 percent weight of the total bulk material composition and one or more ceramics or metals in an amount of 10 to 80 percent weight of the total bulk material composition.

17. The method of claim 7, wherein the one or more dopants comprise one or more ceramic materials or one or more metals.

18. The method of claim 17, wherein the one or more dopants comprise one or more ceramic materials comprising one or more of Y₃Al₅O₁₂ (YAG), Y₄Al₂O₉ (YAM), Er₂O₃, Gd₂O₃, Gd₃Al₅O₁₂ (GAG), YF₃, Al₂O₃, Y₂O₃, YOF, Nd₂O₃, Er₄Al₂O₉, Er₃Al₅O₁₂ (EAG), ErAlO₃, Gd₄Al₂O₉, GdAlO₃, Nd₃Al₅O₁₂, Nd₄Al₂O₉, NdAlO₃, a ceramic compound composed of Y₄Al₂O₉ and a solid-solution of Y₂O₃—ZrO₂, or a ceramic material characterized as high-performance material (HPM ceramic).

19. The method of claim 17, wherein the one or more dopants comprise one or more metals comprising one or more of Si, Al, Y, Er, Mg, Gd, Ti, Zr, Nd, Ce, La, Hf, or Ca.

20. The method of claim 7, wherein the bulk material comprises silicon carbide in an amount of 20 to 90 percent weight of the total bulk material composition and one or more ceramics or metals in an amount of 10 to 80 percent weight of the total bulk material composition.
